(19) United States
(12) Patent Application Publication
(10) Pub. No.: US 2008/0236661 A1
(43) Pub. Date: Oct. 2, 2008

(54) Solar cell

(75) Inventors: Fu-Yuan Yao, Taoyuan Hsien (TW); Shih-Peng Chen, Taoyuan Hsien (TW); Tai-Kang Shing, Taoyuan Hsien (TW)

Correspondence Address: BIRCH STEWART KOLASCH & BIRCH, PO BOX 747, FALLS CHURCH, VA, 22040-0747, US

(73) Assignee: DELTA ELECTRONICS INC.

(21) Appl. No.: 11/882,896

(22) Filed: Aug. 7, 2007

(30) Foreign Application Priority Data
Mar. 30, 2007 (TW) 96111217

(51) Int. Cl. H01L 31/04

(52) U.S. Cl. 136/256; 136/252

(57) ABSTRACT

A solar cell is provided. The solar cell includes a substrate, at least one first photo-electric conversion unit, at least one second photo-electric conversion unit and a reflective layer. The first photo-electric conversion unit and the second-electric conversion unit are disposed on the substrate. The reflective layer is disposed between the first photo-electric conversion unit and the second photo-electric conversion unit. The reflective layer comprises a plurality of thin films having at least two kinds of refractive indices and alternately stacked.

### BACKGROUND OF THE INVENTION

1. Field of the Invention

The invention relates to a solar cell and more particularly to a solar cell having an optically reflective device.

2. Description of the Related Art

Solar cells are different from general cells. A solar cell is a device converting solar energy into electrical energy. A solar cell uses a semiconductor PN junction to obtain electric power and does not require electrolytes for ion conductivity.

A solar cell is a photo-electric semiconductor generating electric power directly from sunlight, and using sunlight as a power generating energy source. A solar cell is fabricated by doping impurities to a highly pure semiconductor material to obtain different characteristics, for example, doping boron to form a P-type semiconductor material or doping phosphorus to form an N-type semiconductor material. After forming a PN junction by combining P-type and N-type semiconductor materials, a solar cell is thus formed. When sunlight is captured by the solar cell, electron-hole pairs are generated. When a current is induced by the generated electron-hole pairs, electric power is generated by the solar cell.

There are various types of solar cells, classified according to materials they include, but are not limited to, single crystal solar cells, polycrystal silicon solar cells and amorphous silicon (a-Si) solar cells. The performance of solar cells is defined according to photo-electrical energy conversion efficiency. One method for improving photo-electrical energy conversion efficiency comprises to fabricate a tandem cell. A tandem cell is fabricated by stacking two or more solar cell devices. The upper stacked solar cell device is used to absorb a spectrum with higher energy, and the lower stacked solar cell, device is used to absorb a spectrum with lower energy. Photon energy can be absorbed by stacking solar cell devices having different materials.

FIG. 1 shows a cross section of a conventional tandem solar cell. Only basic required components are illustrated and described for brevity. Referring to FIG. 1, the conventional tandem solar cell 1 comprises at least a first photo-electric conversion unit 12, a second photo-electric conversion unit 14, a reflective layer 13, a top glass substrate 11, a bottom glass substrate 16 and an electrode 15. The electrode 15 is disposed on the bottom glass substrate 16, the reflective layer 13 is disposed between the first photo-electric conversion unit 12 and the second photo-electric conversion unit 14, and the top glass substrate 11 is disposed on the first photo-electric conversion unit 12.

The top glass substrate 11 is a transparent substrate. When a light 17 is incident through the glass substrate 11, a portion of the light 17 is reflected to the first photo-electric conversion unit 12 by the reflective layer 13. And a portion of the light 17 passes through the reflective layer 13 and is incident to the second photo-electric conversion unit 14. Namely, when a light 17 is incident through the glass substrate 11, a portion of the light 17 in short-wave band is reflected to the first photo-electric conversion unit 12 by the reflective layer 13 due to the material characteristics of the reflective layer 13, and the first photo-electric conversion unit 12 absorbs a portion of the light 17 in short-wave band repeatedly. A portion of the light 17 in long-wave band is incident into the second photo-electric conversion unit 14 passing through the reflective layer 13 and is absorbed by the second photo-electric conversion unit 14.

The reflective layer 13 has different interference effects with various thicknesses. The thickness of the reflective layer 13 must be adjusted to within a specific range to show a higher reflectivity in short-wave band and a lower reflectivity in long-wave band. However, different materials of the reflective layer 13 lead to different refractive indices, and the thickness requirements are thus different. FIG. 2 illustrates a graph of reflectivity percent versus wavelength for various reflective layers. When zinc oxide (ZnO) is used as the reflective layer, the thickness of zinc oxide (ZnO) must reach 3000 nm for a high reflectivity in short-wave band of about 62%. When indium tin oxide (ITO) is used as the reflective layer, the thickness of indium tin oxide (ITO) must reach 2500 nm for a high reflectivity in short-wave band of about 40%.

The reflective layer 13 allows the first photo-electric conversion unit 12 and the second photo-electric conversion unit 14 to have a series connected electrically conductive relationship. The series resistance can be reduced with a thinner reflective layer. For requirements of lower series resistance, the thickness of the reflective layer must be reduced. However, the reduced thickness of the reflective layer does not satisfy the requirements of solar cell reflectivity, and the reflective effect of a single reflective layer will be relatively less. Thus, the conventional solar cell has several problems, which have yet to be solved.

### BRIEF SUMMARY OF INVENTION

A detailed description is given in the following embodiments with reference to the accompanying drawings.

To solve the above described problems, the invention provides a solar cell comprised of a plurality of thin films having high refractive indices and alternately stacked, to improve light energy absorption in the solar cell.

The invention also provides the stacked thin films described above to improve photo-electric conversion efficiency in the solar cell.

An exemplary embodiment of a solar cell comprises: a substrate; at least one first and one second photo-electric conversion unit disposed on the substrate; an optically reflective device disposed between the first photo-electric conversion and the second photo-electric conversion unit, wherein the optically reflective device comprises a plurality of thin films having at least two kinds of refractive indices and alternately stacked.

The solar cell as described in the exemplary embodiment, wherein the first photo-electric conversion unit further comprises: a first semiconductor layer; a first N-type semiconductor layer and a first P-type semiconductor layer, wherein the first semiconductor layer is disposed between the first N-type semiconductor layer and the first P-type semiconductor layer, and a material of the first semiconductor layer comprises amorphous silicon.

The solar cell as described in the exemplary embodiment, wherein the optically reflective device comprises at least three thin films and the thin films comprise a transparent conductive layer or a dielectric layer.

The solar cell as described in the exemplary embodiment, wherein a reflective index of the (n+1)^{th} level of the thin films is different from reflective indices of the n^{th} and (n+2)^{th} levels of the thin films, and n is positive real number.

The solar cell as described in the exemplary embodiment, wherein the nth and (n+2)^{th} levels of the thin films have the same or different reflective indices.

The solar cell as described in the exemplary embodiment, wherein the reflective index of the (n+1)^{th} level of the thin films is larger or smaller than those of the n^{th} and (n+2)^{th} levels of the thin films, and the reflective indices of the thin films are between 1.3 and 5.6.

The solar cell as described in the exemplary embodiment, wherein a wavelength of the light incident to the optically reflective device is between 300 nm and 2500 nm, and a light is incident to the optically reflective device and the second photo-electric conversion unit through the first photo-electric conversion unit, and part of the light is reflected back to the first photo-electric conversion unit by the optically reflective device.

The solar cell as described in the exemplary embodiment, wherein the optically reflective device comprises material such as dielectric material comprising oxide or nitride. Preferably, the optically reflective device comprises indium tin oxide (ITO), zinc oxide (ZnO) or tin oxide (TiO).

The solar cell as described in the exemplary embodiment, further comprises an electrode on the substrate and a cover layer on the substrate covering the first and second photo-electric conversion units, wherein the cover layer comprises indium tin oxide (ITO), and the substrate comprises a glass substrate or a quartz substrate or other suitable materials.

An exemplary embodiment of a solar cell of the invention has an optically reflective device with high/low refractive indices and alternately stacked. The incident light with a specific wavelength range may be selectively reflected through the stacked optically reflective device, the reflectivity of the optically reflective device is increased, and the photo-electric conversion efficiency of the solar cell is improved.

### BRIEF DESCRIPTION OF DRAWINGS

The invention can be more fully understood by reading the subsequent detailed descriptions and examples with references made to the accompanying drawings, wherein:

FIG. 1 shows a cross section of a conventional tandem solar cell.

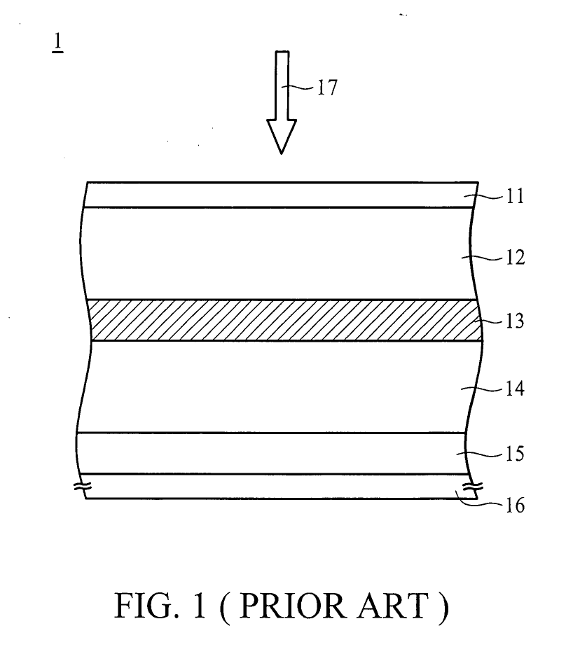

FIG. 2 is a graph of reflectivity percent versus wavelength for various reflective layers.

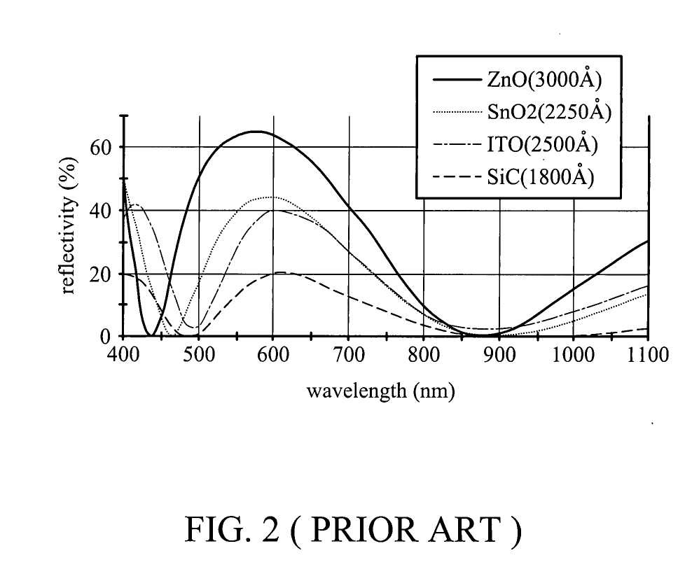

FIG. 3 is a diagram showing an exemplary embodiment of a solar cell of the invention.

FIG. 4 is a graph of reflectivity percent versus wavelength for various optically reflective devices in embodiments of the invention.

### DETAILED DESCRIPTION OF INVENTION

The following description is of the best-contemplated mode of carrying out the invention. This description is made for the purpose of illustrating the general principles of the invention and should not be taken in a limiting sense. The scope of the invention is best determined by reference to the appended claims. Wherever possible, the same reference numbers are used in the drawings and the descriptions to refer the same or like parts.

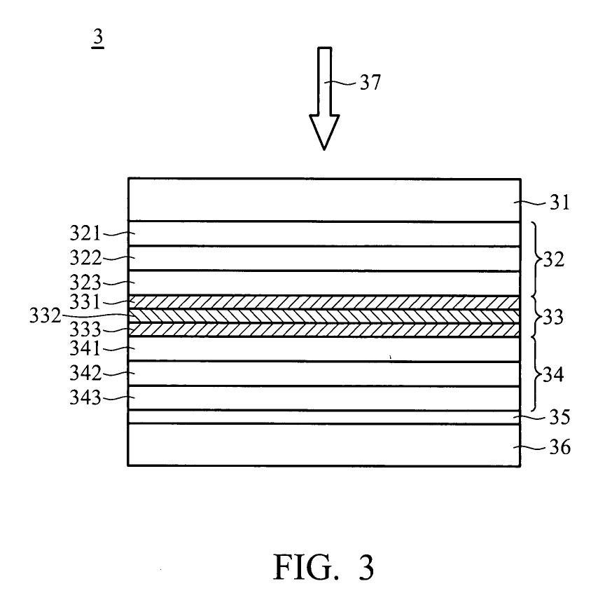

FIG. 3 illustrates a diagram showing an exemplary embodiment of a solar cell of the invention. One exemplary embodiment of a solar cell 3 comprises at least a first photo-electric conversion unit 32, an optically reflective device 33, a second photo-electric conversion unit 34 and a substrate 36. The optically reflective device 33 is disposed between the first photo-electric conversion unit 32 and the second photo-electric conversion unit 34. The second photo-electric conversion unit 34 and the first photo-electric conversion unit 32 are stacked on the substrate 36 in sequence, and the first photo-electric conversion unit 32 is located on a light incident plane. A more detailed description of the structure and disposed relationship between the first photo-electric conversion unit 32, the second photo-electric conversion unit 34 and the optically reflective device 33 are described below.

In one embodiment, the first photo-electric conversion unit 32 absorbs solar energy with a wavelength in short-wave band with higher energy, and the wavelength is between 300 nm and 700 nm. The second photo-electric conversion unit 34 absorbs solar energy with a wavelength in long-wave band with lower energy, and the wavelength is between 700 nm and 2500 nm.

In the embodiment, the first photo-electric conversion unit 32 comprises a first N-type semiconductor layer 323 comprising un-doped amorphous silicon (α-Si), a first semiconductor layer 322 comprising n-doped amorphous silicon and a first P-type semiconductor layer 321 comprising p-doped amorphous silicon. The N-type semiconductor layer 323, the first semiconductor layer 322 and the first P-type semiconductor layer 321 are disposed above the second photo-electric conversion unit 34 in sequence. The first semiconductor layer 322 comprises.

Additionally, the second photo-electric conversion unit 34 comprises a second N-type semiconductor layer 343 comprising n-doped microcrystalline silicon, a second semiconductor layer 342 comprising microcrystalline amorphous silicon and a second P-type semiconductor layer 341 comprising p-doped microcrystalline silicon. The N-type semiconductor layer 343, the second semiconductor layer 342 and the P-type semiconductor layer 341 are disposed above the substrate 36 in sequence. The substrate 36 comprises a glass substrate, a quartz substrate or other appropriate material substrates.

Referring to FIG. 3, the optically reflective device 33 is disposed between the first photo-electric conversion unit 32 and the second photo-electric conversion unit 34. The optically reflective device 33 comprises oxide or nitride, for example, indium tin oxide (ITO), zinc oxide (ZnO), tin oxide (TiO) or other suitable conductive materials.

Additionally, the solar sell in one preferred embodiment of the invention further comprises a cover layer 31 and an electrode 35 disposed on the substrate 36. The cover layer 31 covers the first photo-electric conversion unit 32 and the second photo-electric conversion unit 34, wherein materials of the cover layer 31 comprise of, for example, indium tin oxide (ITO) or other suitable materials. The electrode 35 is disposed on the substrate 36, wherein materials of the electrode 35 comprise of, for example, metals, alloys or other appropriate materials.

Referring to FIG. 3, in the embodiment, the optically reflective device 33 comprises a plurality of thin films having at least two kinds of refractive indices and alternately stacked between the first photo-electric conversion unit 32 and the second photo-electric conversion unit 34 to improve photo-electric conversion performance of tandem solar cells, and the refractive index of the optically reflective device 33 is between 1.3 and 5.6; preferably between 1.4 and 2.6. In the embodiment, the optically reflective device 33 is comprised of the thin films with low/high or high/low refractive indices and alternately stacked. In the embodiment, the optically reflective device 33 comprises at least three thin films comprising a first dielectric layer 331, a second dielectric layer 332 and a third dielectric layer 333, wherein the second dielectric layer 332 and other two dielectric layers have different materials. Materials of the second dielectric layer 332 comprise, for example, zinc oxide (ZnO) with a refractive index of about 1.4, silicon carbide (SiC) with a refractive index of about 2.6, or indium tin oxide (ITO) with a refractive index of about 1.8. In the embodiment, the first dielectric layer 331 and the third dielectric layer 333 may have the same or different materials.

Additionally, the refractive index of the second dielectric layer 332 is different from those of the other two dielectric layers due the different material used. For example, the refractive index of the second dielectric layer 332 is smaller than those of the first dielectric layer 331 and the third dielectric layer 333. Alternatively, the refractive index of the second dielectric layer 332 may also larger than those of the first dielectric layer 331 and the third dielectric layer 333. In the embodiment, the first dielectric layer 331 and the third dielectric layer 333 may have the same refractive indices.

For example, when a light 37 is incident to the stacked solar cell 3, the light 37 is incident to the optically reflective device 33 and the second photo-electric conversion unit 34 through the first photo-electric conversion unit 32, wherein a part of the light 37 is reflected back to the first photo-electric conversion unit 32 by the optically reflective device 33, and another part of the light 37 is incident to the second photo-electric conversion unit 34. In the embodiment, a wavelength of the light 37 is between 300 nm and 2500 nm, wherein a wavelength of the light 37 reflected back to the first photo-electric conversion unit 32 by the optically reflective device 33 is between 300 nm and 700 nm, and a wavelength of the light 37 is incident to the second photo-electric conversion unit 34 through the optically reflective device 33 is between 700 nm and 2500 nm. Also, a wavelength of the light 37 reflected back to the first photo-electric conversion unit 32 from the optically reflective device 33 is between 700 nm and 2500 nm, and a wavelength of the light 37 is incident to the second photo-electric conversion unit 34 through the optically reflective device 33 is between 300 nm and 700 nm.

In the embodiment, it is illustrated that the optically reflective device 33 is comprised of a plurality of dielectric layers having different refractive indices and alternately stacked. Thus, when the light 37 is incident to the solar cell 3 through the cover layer 31, the light 37 is reflected to the first photo-electric conversion unit 32 by the first dielectric layer 331 as a first reflection. When the light 37 passes through the second dielectric layer 332, the light 37 is reflected to the first photo-electric conversion unit 32 as a second reflection by the second dielectric layer 332. Next, when the light 37 passes through the third dielectric layer 333, the light 37 is reflected to the first photo-electric conversion unit 32 as a third reflection by the third dielectric layer 333. As described above, the light 37 may be reflected to the first photo-electric conversion unit 32 repeatedly. More and more electron-hole pairs are thus generated and formed in the first photo-electric conversion unit 32. Due to the optically reflective device 33 comprising of a plurality of dielectric layers having different refractive indices and alternately stacked the light 37 is incident to the first photo-electric conversion unit 32 with a higher reflectivity in long-wave or short-wave band because of interference of the light.

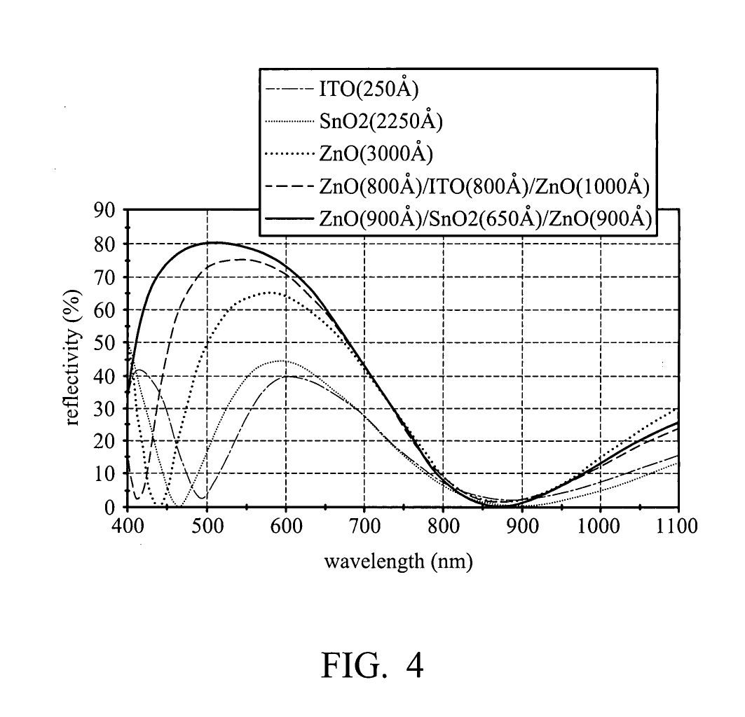

FIG. 4 is a graph of reflectivity percent versus wavelength for various optically reflective devices in embodiments of the invention. In one embodiment, components of the optically reflective device 33 comprise, for example, ZnO with a thickness of about 900 nm for the first dielectric layer 331, SnO₂ with a thickness of about 650 nm for the second dielectric layer 332 and ZnO with a thickness of about 9000 nm for the third dielectric layer 333. In another embodiment, components of the optically reflective device 33 comprise, for example, ZnO with a thickness of about 800 nm for the first dielectric layer 331, ITO with a thickness of about 800 nm for the second dielectric layer 332 and ZnO with a thickness of about 1000 nm for the third dielectric layer 333. The components of the optically reflective device 33 are not limited to the disclosed embodiments and can be defined according to existing processes by those skilled in the Art. In other words, the optically reflective device 33 may be comprised of any one of the disclosed components.

Compared with the conventional electronic photo-voltaic cells using a ZnO single layer as the reflective layer, an exemplary embodiment of a solar cell can achieve a 15% increase in reflectivity, and a 600nm decrease in the reflective layer thickness. Compared with the conventional electronic photo-voltaic cell using an ITO single layer as the reflective layer, an exemplary embodiment of a solar cell can achieve a 35% increase in reflectivity with the same reflective layer thickness. Compared with the conventional electronic photo-voltaic cell using a TiO single layer as the reflective layer, an exemplary embodiment of a solar cell can achieve a 40% increase in reflectivity, and a 200 nm decrease in the reflective layer thickness. In the embodiment, a reflective wavelength of the optically reflective device 33 is between 300 nm and 2500 nm. In one embodiment, the optically reflective device 33 has a higher reflectivity of about 75% to 80% to a wave in short-wave band. Compared with conventional solar cells, an exemplary embodiment of a solar cell has higher reflectivity and reduced thickness of the reflective layer resulting in better photo-electric conversion efficiency.

Some advantages of the exemplary embodiment of the solar cell are described as follows. The optically reflective device is comprised of a plurality of thin films having different kinds of refractive indices and is alternately stacked. When the light is incident through the solar cell, the incident light with a specific wavelength, range may,be selectively reflected by the stacked optically reflective device composed of a plurality of thin films having high/low refractive indices. The reflectivity of the optically reflective device is thus increased, and the photo-electric conversion efficiency of the solar cell is improved. Compared with conventional tandem solar cells, an exemplary embodiment of the optically reflective device has a decrease in thickness. Thus, the series resistance of an exemplary embodiment of the solar cell can be reduced to improve device performances.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A solar cell comprising:
a substrate;
at least one first and one second photo-electric conversion unit disposed on the substrate; and
an optically reflective device disposed between the first photo-electric conversion unit and the second photo-electric conversion unit, wherein the optically reflective device comprises a plurality of thin films having at least two different refractive indices and stacked together.

2. The solar cell as claimed in claim 1, wherein the first photo-electric conversion unit further comprises:
a first semiconductor layer; and
a first N-type semiconductor layer and a first P-type semiconductor layer,
wherein the first semiconductor layer is disposed between the first N-type semiconductor layer and the first P-type semiconductor layer.

3. The solar cell as claimed in claim 2, wherein the first semiconductor layer comprises amorphous silicon, the first N-type semiconductor layer comprises n-doped amorphous silicon and the first P-type semiconductor layer comprises p-doped amorphous silicon.

4. The solar cell as claimed in claim 1, wherein the second photo-electric conversion unit further comprises:
a second semiconductor layer; and
a second N-type semiconductor layer and a second P-type semiconductor layer, wherein the second semiconductor layer is disposed between the second N-type semiconductor layer and the second P-type semiconductor layer.

5. The solar cell as claimed in claim 4, wherein the second semiconductor layer comprises microcrystalline silicon, the second N-type semiconductor layer comprises n-doped microcrystalline silicon and the second P-type semiconductor layer comprises p-doped microcrystalline silicon.

6. The solar cell as claimed in claim 1, wherein the optically reflective device comprises at least three thin films and the thin films comprise a transparent conductive layer or a dielectric layer.

7. The solar cell as claimed in claim 6, wherein the reflective index of the (n+1)^{th} level of the thin films is different from those of the n^{th} and (n+2)^{th} levels of the thin films, and n is a positive real number.

8. The solar cell as claimed in claim 7, wherein the n^{th} and (n+2)^{th} levels of the thin films have the same reflective indices or different reflective indices.

9. The solar cell as claimed in claim 7, wherein the reflective index of the (n+1)^{th} level of the thin films is greater or smaller than those of the n^{th} and (n+2)^{th} levels of the thin films.

10. The solar cell as claimed in claim 6, wherein the reflective indices of the thin films are between 1.3 and 5.6.

11. The solar cell as claimed in claim 6, wherein a material of the dielectric layer comprises zinc oxide (ZnO) having a reflective index of about 1.4.

12. The solar cell as claimed in claim 6, wherein a material of the dielectric layer comprises silicon carbide (SiC) having a reflective index of about 2.6.

13. The solar cell as claimed in claim 6, wherein a material of the dielectric layer comprises indium tin oxide (ITO) having a reflective index of about 1.8.

14. The solar cell as claimed in claim 1, wherein a light is incident to the optically reflective device and the second photo-electric conversion unit via the first photo-electric conversion unit, and the light is reflected back to the first photo-electric conversion unit from the optically reflective device.

15. The solar cell as claimed in claim 14, wherein a wavelength of the light is incident to the optically reflective device is between 300 Å to 2500 Å.

16. The solar cell as claimed in claim 14, wherein a wavelength of the light reflected back to the first photo-electric conversion unit is between 300 Å and 700 Å, and a wavelength of the light incident to the second photo-electric conversion unit is between 700 nm and 2500 nm.

17. The solar cell as claimed in claim 14, wherein a wavelength of the light reflected back to the first photo-electric conversion unit is between 700 nm and 2500 nm, and a wavelength of the light incident to the second photo-electric conversion unit is between 300 nm and 700 nm.

18. The solar cell as claimed in claim i, wherein the optically reflective device comprises oxide, nitride, indium tin oxide (ITO), zinc oxide (ZnO), tin oxide (TiO) or a conductive material.

19. The solar cell as claimed in claim 1, further comprising an electrode on the substrate and a cover layer on the substrate for covering the first and second photo-electric conversion units, wherein the electrode comprises metals or alloys, and the cover layer comprises indium tin oxide (ITO).

20. The solar cell as claimed in claim 1, wherein the substrate comprises a glass substrate or a quartz substrate.
